(19) United States
(12) Patent Application Publication
(10) Pub. No.: US 2019/0096489 A1
(43) Pub. Date: Mar. 28, 2019

(54) Read-only operation of non-volatile memory module

(71) Applicant: Intel Corporation, Santa Clara, CA (US)

(72) Inventors: Stanislaw Mosiolek, Gdansk (PL); Jakub Radtke, Gdansk (PL)

(21) Appl. No.: 15/718,090

(22) Filed: Sep. 28, 2017

(51) Int. Cl. G11C 16/22; G11C 16/08; G06F 11/07; G11C 5/14

(52) U.S. Cl. CPC G11C 16/22; G11C 16/08; G11C 5/141; G06F 11/0727; G06F 11/0751

(57) ABSTRACT

A non-volatile memory module and a read-only operation of the non-volatile memory module are disclosed. A non-volatile memory module such as a non-volatile dual in-line memory module (NVDIMM) may, in response to a command from a host, set a particular memory range of the memory module as a read-only state by storing an address of the memory range with a secret associated with the memory range in an internal database of the memory module. The memory module may then reject a write command to the memory range in the read-only state. The internal database is stored within the memory module and the write protection is implemented inside the memory module so that no external entity may change the protected memory region.

### FIELD

Examples relate to a computer memory module, a system, and a method of operating the computer memory module. More particularly, examples relate to a non-volatile memory module and a read-only operation of the non-volatile memory module.

### BACKGROUND

A non-volatile memory module, such as a non-volatile dual in-line memory module (NVDIMM), has been used for a computer system. An NVDIMM is a random-access memory module used in computers. There are several different types of NVDIMMs that are currently in use. For example, one type of NVDIMM includes both a volatile memory and a non-volatile memory and may retain its contents when an electrical power is removed due to an unexpected power loss, system crash, normal shutdown, or the like. The system may use the volatile memory during normal operation and copy the contents from the volatile memory to the non-volatile memory in case of power failure using a backup power source. Another type of NVDIMM may use a non-volatile memory for normal operation.

The address space of the non-volatile memory module (e.g. the address space of the conventional NVDIMM) may be exposed to an operating system (OS). Such address space can be utilized by the OS in many different ways, e.g. can be mapped to applications address space as a non-volatile directly-addressed memory region. Currently there is no possibility to mark such memory region as read-only.

Conventional solutions rely on file attributes and user privileges for write protection. An OS defines a superuser (e.g. a root in Linux, an administrator in Windows, etc.) which can do read/write to every file and every memory locations. It means that there is no real protection against write. Currently, there is no way to define a content on an NVDIMM in a way that it cannot be changed later on.

### BRIEF DESCRIPTION OF THE FIGURES

Some examples of apparatuses and/or methods will be described in the following by way of example only, and with reference to the accompanying figures, in which

FIG. 1 shows an example of a system including a processor and a memory;

FIG. 2 shows an example of a non-volatile memory module;

FIG. 3 shows an example of setting a range of memory address space of the NVDIMM as read-only;

FIG. 4 shows an example of state transitions of a memory region between read/write and read-only states;

FIG. 5 is a flow chart of an example method for setting a writing protection in an NVDIMM;

FIG. 6 shows a concept of an example use case of the write protection mechanism for content authentication; and

FIG. 7 is a block diagram of an example device in which the non-volatile memory module of FIG. 2 may be used.

### DETAILED DESCRIPTION

Various examples will now be described more fully with reference to the accompanying drawings in which some examples are illustrated. In the figures, the thicknesses of lines, layers and/or regions may be exaggerated for clarity.

Accordingly, while further examples are capable of various modifications and alternative forms, some particular examples thereof are shown in the figures and will subsequently be described in detail. However, this detailed description does not limit further examples to the particular forms described. Further examples may cover all modifications, equivalents, and alternatives falling within the scope of the disclosure. Like numbers refer to like or similar elements throughout the description of the figures, which may be implemented identically or in modified form when compared to one another while providing for the same or a similar functionality.

It will be understood that when an element is referred to as being “connected” or “coupled” to another element, the elements may be directly connected or coupled or via one or more intervening elements. If two elements A and B are combined using an “or”, this is to be understood to disclose all possible combinations, i.e. only A, only B as well as A and B. An alternative wording for the same combinations is “at least one of A and B”. The same applies for combinations of more than 2 Elements.

The terminology used herein for the purpose of describing particular examples is not intended to be limiting for further examples. Whenever a singular form such as “a,” “an” and “the” is used and using only a single element is neither explicitly or implicitly defined as being mandatory, further examples may also use plural elements to implement the same functionality. Likewise, when a functionality is subsequently described as being implemented using multiple elements, further examples may implement the same functionality using a single element or processing entity. It will be further understood that the terms “comprises,” “comprising,” “includes” and/or “including,” when used, specify the presence of the stated features, integers, steps, operations, processes, acts, elements and/or components, but do not preclude the presence or addition of one or more other features, integers, steps, operations, processes, acts, elements, components and/or any group thereof.

Unless otherwise defined, all terms (including technical and scientific terms) are used herein in their ordinary meaning of the art to which the examples belong.

Examples are disclosed to provide a write protection to a particular memory address range of a non-volatile memory module. In some examples, the write protection may be implemented by using “set read-only” and “unset read-only” operations. The interface of the memory module is extended by new methods including the “set read-only” and “unset read-only” operations.

In the examples disclosed herein, the write protection is implemented inside the non-volatile memory module either by firmware or hardware of the memory module. A superuser (e.g. a root in Linux, an administrator in Windows, etc.) may not even be able to change the read-only memory region defined for the memory module. Embedded processors in the conventional systems can potentially be configured to bypass the read-only memory protection. However, in the examples disclosed herein, the write protection is implemented inside the memory module so that no external entity may change the protected memory region.

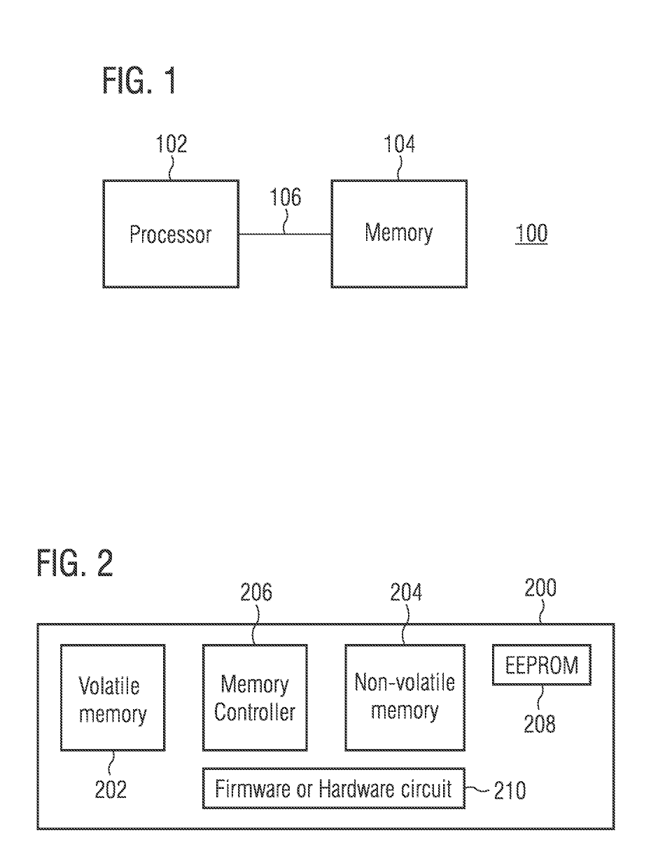

FIG. 1 shows an example of a system 100 including a processor 102 and a memory 104. The processor 102 may include one or more processing cores, each of which may include a cache memory and/or a memory controller. The processor 102 may communicate with the memory 104 via a system bus 106. The memory 104 may include one or more memory modules, each of which may include a memory controller.

The memory module may be a non-volatile memory module, i.e. a memory module including one or more non-volatile memory chips or storages. The non-volatile memory module may be in any type of package and form factor. For example, the non-volatile memory module may be dual in-line memory module (DIMM), small outline DIMM (SO-DIMM), micro DIMM, single in-line memory module (SIMM), memory stick, memory card, package-in-package, or any type of package that is currently existing or may be developed in the future.

Hereafter, the examples will be explained with reference to NVDIMM. However, it should be noted that the examples are not limited to NVDIMM, but may be applied to any type of non-volatile memory modules.

FIG. 2 shows an example of an NVDIMM 200. The NVDIMM 200 may use a conventional DIMM package. The NVDIMM 200 may include a non-volatile memory 204 and a firmware or hardware circuit 210 (i.e. a controller for implementing the write protection mechanism in accordance with the examples disclosed herein). The NVDIMM 200 may include a memory controller 206. Alternatively, the memory controller 206 may be included in a processor 102 and not in the NVDIMM 200. Alternatively, the NIDIMM 200 may include a volatile memory 202. Alternatively, the NVDIMM 200 may not include a volatile memory 202 and may be paired with a separate regular DIMM (e.g. a volatile memory module) connected through the system bus 106. Alternatively, the NVDIMM 200 may not be paired or associated with another volatile memory module.

In some examples, the non-volatile memory 204 may be used for normal operations of the system. Alternatively, the volatile memory 202 may be used during the normal operations and the contents of the volatile memory 202 may be copied to the non-volatile memory 204 by the memory controller 206 if the system power fails, such as an unexpected power loss, a system crash, or a normal shutdown occurs. The contents copied in the non-volatile memory 204 may be restored back to the volatile memory 202 by the memory controller 206 after the power is recovered. If the non-volatile memory 204 is used for normal operations, the contents of the non-volatile memory may not be lost upon power failure and it may not be needed to copy the contents from the memory module 200.

The volatile memory 202 may be any type of volatile memory, such as a dynamic random access memory (DRAM), or the like. The non-volatile memory 204 may be any type of non-volatile memory, such as a flash memory, a memory using a phase change memory (PCM) technology, or any other type of non-volatile memory that is currently existing or may be developed in the future. The system 100 may include a back-up power source (not shown), such as a supercapacitor, a back-up battery, or the like, to provide power for operations of the memory module for a limited duration after power interruption.

A range of memory spaces of the NVDIMM 200 may be configured as a read-only region such that the memory region may be protected against an unauthorized modification. The read-only region of the NVDIMM 200 may be loaded with data (e.g. sensitive data) or instruction codes to which a write protection may be given.

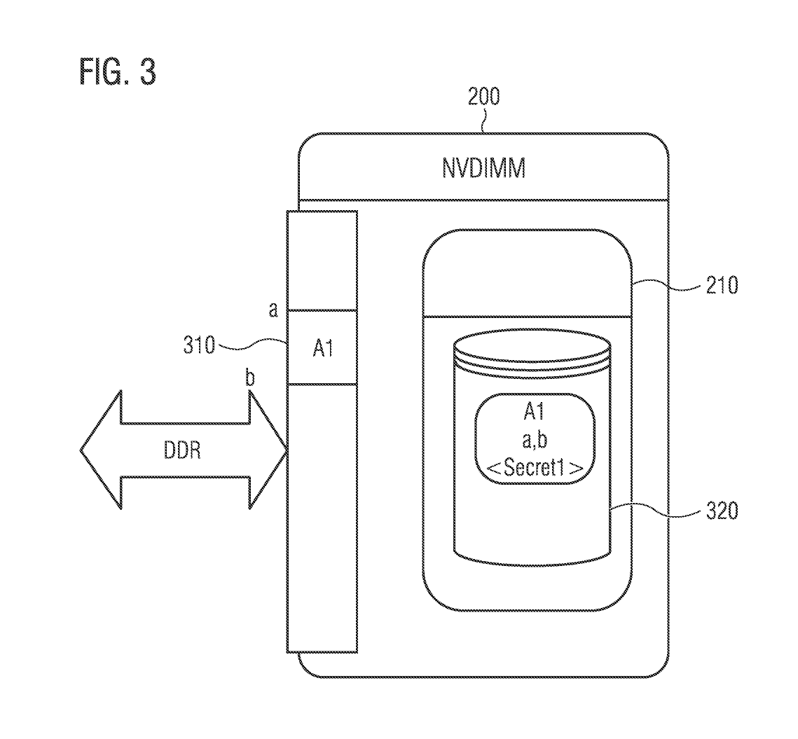

FIG. 3 shows an example of setting a specific range of memory address spaces of the NVDIMM 200 as read-only. Consider a memory range A1 310 of the NVDIMM 200 is exposed to the OS. The memory region A1 310 begins at address ‘a’ and ends at address ‘b’. Normally, the OS can read from, and write into, the memory region A1 310, for example using a double data rate (DDR) interface. The DDR interface may be any versions of the existing DDR interfaces, or any other versions or variations of the DDR interface that may be developed in the future.

In examples, a region of memory spaces of the NVDIMM 200 may be set as read-only by using a “Set Read-Only” command and the read-only memory region may be unlocked (i.e. changed to a read/write state) by using an “Unset Read-Only” command. The Set Read-Only command includes an address of the memory region A1 310 and a secret (e.g. a password, a hash, a code, an identifier that is generated based on the password, the hash, the code, or any other identifier, or the like) to be associated with the memory region A1 310. The Unset Read-Only command includes the address of the memory region A1 310 (or any identifier that can uniquely identify the address of the memory region A1 310, for example a universally unique identifier (UUID) that may be obtained as a result of the Set Read-Only command) and the associated secret in order to successfully unlock the memory region A1 to the read/write state. The Set Read-only and Unset Read-Only commands are new interfaces defined for the NVDIMM 200 to set a memory range of the NVDIMM 200 as read-only and set the memory range of the NVDIMM 200 as read/write, respectively.

After the OS issues a Set Read-Only command for a memory region A1 310 to the NVDIMM 200, the NVDIMM 200 adds the memory region A1 to an internal database 320 (e.g. stores the address range of the memory region A1 310 and the associated secret in the internal database 320). The internal database 320 is stored within the NVDIMM 200. For example, the internal database 320 may be stored in the non-volatile memory 204 of the NVDIMM 200. Alternatively, the internal database 320 may be stored in a table in the electrically erasable programmable read-only memory (EEPROM) 208 installed on the NVDIMM 200 or may be stored in the NVDIMM 200 as a part of metadata stored together with the NVDIMM pool configuration. The internal database 320 of the NVDIMM 200 may be accessed by the logic implemented in the firmware of the NVDIMM or by the hardware circuit 210 on the NVDIMM 200. The controller on the NVDIMM 200 (i.e. the firmware or hardware circuit 210 on the NVDIMM 200) may create a new record in the internal database 320, verify the secret (or any information derived based on the secret) for a specific memory address range, or remove or change a data record from the internal database 320, and may perform the functions disclosed herein to set and reset a particular memory range of the NVDIMM 200 as read-only.

Once the memory region A1 310 is set to read-only, the NVDIMM 200 may allow reading from the memory region A1 310, but may reject writing into the memory region A1 310. After the memory region A1 310 has been set as read-only if a host tries to write into the memory region A1 310 of the NVDIMM, the write request will be rejected by the NVDIMM 200 and an error signal may be sent back to the processor via a DDR interface. The secret may be kept in a secure place in the system 100 in a safe manner so that unauthorized components do not have an access to the secret. Alternatively, the secret may be intentionally forgotten by a host such that the memory region A1 310 may be made read-only permanently.

The read-only memory regions may be unlocked (i.e. changed back to a read/write state) by providing the associated secret. For example, the OS may issue an Unset Read-Only command for the memory region A1 310 to the NVDIMM 200 along with the secret that was provided to set the memory region A1 310 as read-only. The firmware of the NVDIMM or the hardware circuit 210 on the NVDIMM 200 may set the memory region A1 310 back to the read/write state if the secret provided with the Unset Read-Only command matches the associated secret in the internal database 320.

The OS may check if the associated secret has been changed. For example, this checking may be performed to prevent the situation that the NVDIMM 200 has been formatted or factory reset has been applied to the NVDIMM 200 and someone has created a read-only region with different contents and secret (since someone else does not know the secret). For example, this checking may be performed by using a new command to the NVDIMM 200 (e.g. a “Check Secret” command). The OS may provide the associated secret with the “Check Secret” command to the NVDIMM 200, and the firmware or the hardware circuit 210 on the NVDIMM may respond with “Success” if the secret provided with the Check Secret command matches the secret in the internal database 320, or “False” if the secret provided with the Check Secret command does not match the secret in the internal database 320.

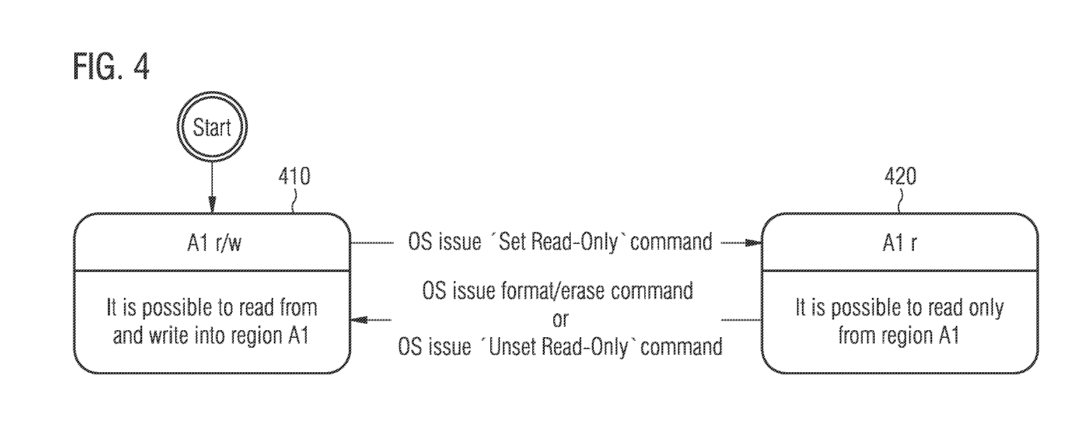

FIG. 4 shows an example of state transitions of a memory region between read/write and read-only states. Initially, the memory region A1 310 may be in a read/write state 410, which means that the OS or applications can read from, and write into, the memory region A1 310. After the OS issues a Set Read-Only command along with a secret to the NVDIMM 200 for the memory region A1 310, the state of the memory region A1 310 changes to a read-only state 420. After transition to the read-only state 420, the OS or applications may read from the memory region A1 310, but may not write into the memory region A1 310. The memory region A1 310 may transition to the read/write state 410 by using an Unset Read-Only command with the associated secret. Alternatively, the memory region A1 310 may switch to the read/write state 410 by issuing a format or erase command.

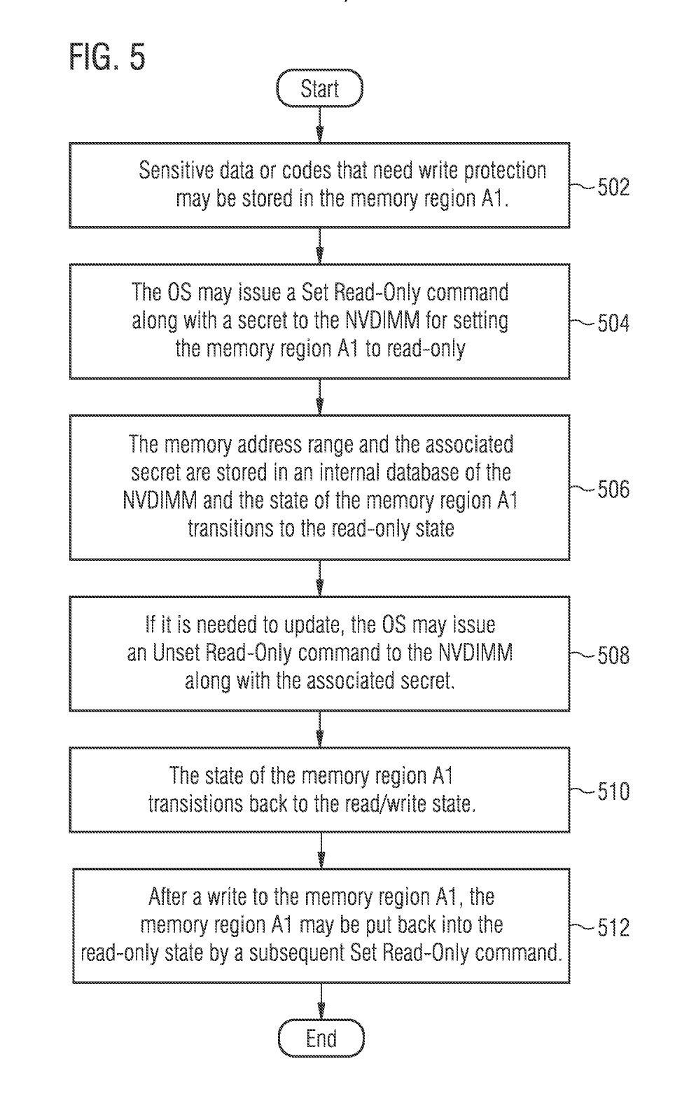

FIG. 5 is a flow chart of an example method for implementing a writing protection for a memory region in an NVDIMM 200. It should be noted that the processing shown in FIG. 5 do not have to be performed in the order as shown in FIG. 5 and may be performed in different order, and some processing may be omitted or repeated (e.g. processing 508 and 510 may be omitted, or processing 512 may be omitted). The memory region A1 may initially be in a read/write state 410. For example, data or codes that need write protection may be stored in the memory region A1 310 (502). After storing the data or codes in the memory region A1 310, the OS may issue a Set Read-Only command along with a secret to the NVDIMM 200 for setting the memory region A1 310 to read-only (504). The memory address range and the associated secret are stored in an internal database 210 of the NVDIMM and the state of the memory region A1 310 transitions to the read-only state 420 (506). After switching to the read-only state 420, the memory region A1 310 may not be overwritten. If it is needed to change the memory region A1 310 back to the read/write state 410 (e.g. in order to update the codes stored in the memory region A1 310), the OS may issue an Unset Read-Only command to the NVDIMM 200 along with the associated secret (508). If the associated secret is verified by the NVDIMM firmware or hardware circuit 210, the state of the memory region A1 310 transitions back to the read/write state 410 (510). After a write to the memory region A1 310, the memory region A1 310 may be put back into the read-only state 420 by a subsequent Set Read-Only command (512).

Conventionally there is no known solution implemented in the NVDIMM 200 to provide a write protection to a specific memory range of the NVDIMM 200. In the examples disclosed herein, a write protection to a memory region which is directly available for a processor for read and execution may be implemented within the NVDIMM 200.

The examples disclosed herein may be used as a hardware security mechanism to secure contents (e.g. executable codes, files, data, programs, etc.) stored in the NVDIMM 200. The examples disclosed herein may be used to secure codes that is executable directly from the NVDIMM 200. The OS does not have to authenticate the codes before execution, but may execute the codes after confirming the secret associated with the memory region that stores the codes. The secret confirmation may be enough to determine if the contents have not been altered or modified.

For example, the OS may put a boot loader into the read-only region of the NVDIMM 200 and keep the secret in a secure manner so that no other components can access it. After power up, the OS may use a command (e.g. a “Check Secret” command) to check if the read-only region (i.e. the boot loader in this example) has not been changed e.g. due to format or factory reset. If the NVDIMM 200 responds with “Success” to the “Check Secret” command, which means that the secrets match, the OS may assume that the boot loader has not been changed and may proceed to boot the rest of the system without additional authentication and copy operation (execution in place). If the OS needs to update the boot loader, the OS may use the Unset Read-Only command to unlock the memory region for updating the boot loader.

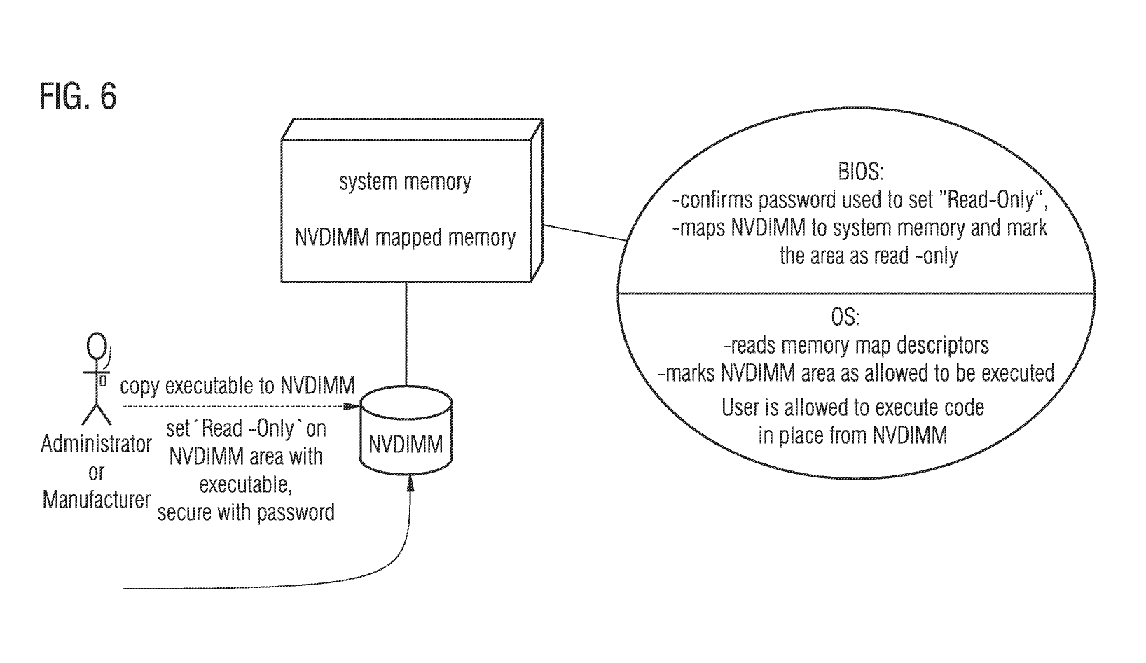

FIG. 6 shows a concept of an example use case of using the write protection mechanism for content authentication. For example, an administrator or manufacture may copy executable codes to the NVDIMM 200 and set the memory region including the executable codes as read-only. For example, the OS may save a confirmation hash in a place that is accessible by the platform basic input-output system (BIOS). The confirmation hash may be generated based on the secret used to set the memory region read-only and a memory region content checksum. After power up, the BIOS may use the confirmation hash to confirm that the memory region is read-only (e.g. via an additional NVDIMM command) and may map the read-only region to the system memory and mark it as “execution” safe (e.g. via an NVDIMM firmware interface table (NFIT)). The OS reads the memory map descriptor and may mark the memory region as allowed to be executed. The OS may execute binaries from the read-only region without additional verification.

In other examples, the contents stored in the NVDIMM 200 may be secured by setting the memory region storing the contents as read-only and by intentionally forgetting the secret associated with the memory region. For example, an administrator or manufacturer may copy sensitive data or codes to the NVDIMM 200 and protect it from modification by setting the memory region including the contents as read-only and intentionally forgetting the secret associated with the memory region. The contents secured this way may not be changed other than by erasing or formatting the NVDIMM 200.

Another example is a computer program having a program code for performing at least one of the methods described herein, wherein the computer program is executed on a computer, a processor, a programmable hardware component, or the like. Another example is a machine-readable storage including machine readable instructions, when executed, to implement a method or realize an apparatus as described herein. A further example is a machine-readable medium including code, when executed, to cause a machine to perform any of the methods described herein. The machine-readable storage or medium may be a non-transient storage or medium.

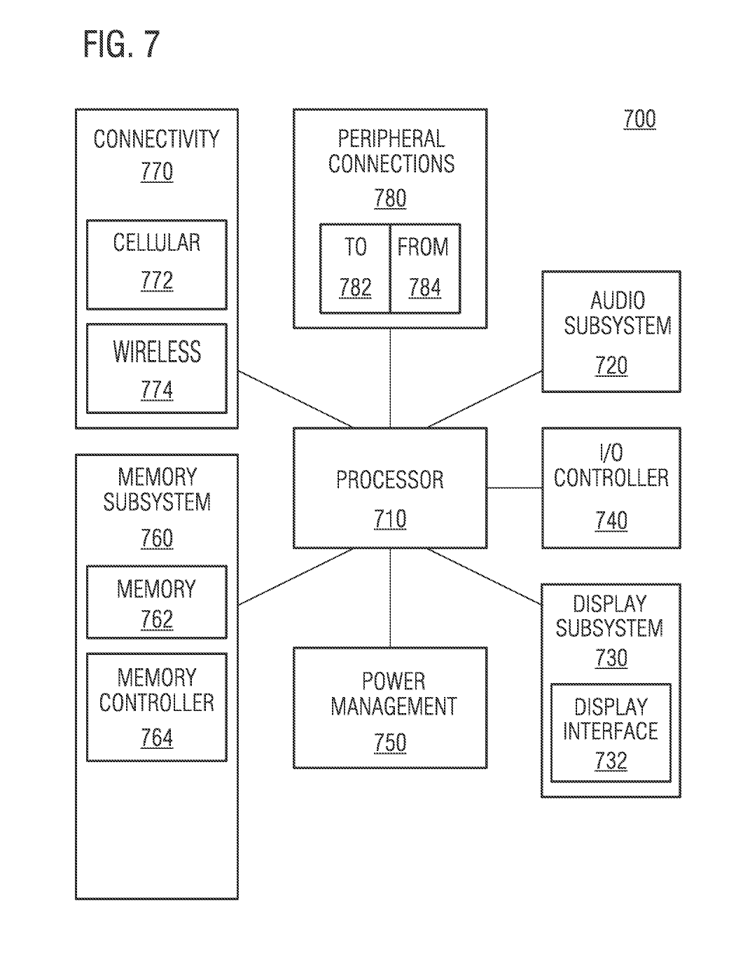

FIG. 7 is a block diagram of an example device, for example a mobile device, in which the non-volatile memory module 200 may be used. For example, device 700 may represent a mobile computing device, such as a computing tablet, a mobile phone or smartphone, a wireless-enabled e-reader, wearable computing device, or other mobile device. It will be understood that certain of the components are shown generally, and not all components of such a device are shown in device 700. It should be noted that some of the components shown in FIG. 7 may be integrated into a single chip or multiple chips. For example, some or all of memory subsystem 760, power management 750, and/or processor 710 may be integrated into a single chip or multiple chips.

Device 700 includes a processor 710, which performs the primary processing operations of device 700. Processor 710 can include one or more physical devices, such as microprocessors, application processors, microcontrollers, programmable logic devices, or other processing means. The processing operations performed by processor 710 include the execution of an operating platform or operating system on which applications and/or device functions are executed. The processing operations include operations related to I/O (input/output) with a human user or with other devices, operations related to power management, and/or operations related to connecting device 700 to another device. The processing operations can also include operations related to audio I/O and/or display I/O.

In one example, device 700 includes an audio subsystem 720, which represents hardware (e.g., audio hardware and audio circuits) and software (e.g., drivers, codecs) components associated with providing audio functions to the computing device. Audio functions can include speaker and/or headphone output, as well as microphone input. Devices for such functions can be integrated into device 700, or connected to device 700. In one example, a user interacts with device 700 by providing audio commands that are received and processed by processor 710.

A display subsystem 730 represents hardware (e.g., display devices) and software (e.g., drivers) components that provide a visual and/or tactile display for a user to interact with the computing device. Display subsystem 730 includes display interface 732, which includes the particular screen or hardware device used to provide a display to a user. In one embodiment, display interface 732 includes logic separate from processor 710 to perform at least some processing related to the display. In one embodiment, display subsystem 730 includes a touchscreen device that provides both output and input to a user. In one example, display subsystem 730 includes a high definition (HD) display that provides an output to a user. High definition can refer to a display having a pixel density of approximately 100 PPI (pixels per inch) or greater, and can include formats such as full HD (e.g., 1080p), retina displays, 4K (ultra-high definition or UHD), or others.

An I/O controller 740 represents hardware devices and software components related to interaction with a user. I/O controller 740 can operate to manage hardware that is part of audio subsystem 720 and/or display subsystem 730. Additionally, I/O controller 740 illustrates a connection point for additional devices that connect to device 700 through which a user might interact with the system. For example, devices that can be attached to device 700 might include microphone devices, speaker or stereo systems, video systems or other display device, keyboard or keypad devices, or other I/O devices for use with specific applications such as card readers or other devices.

As mentioned above, I/O controller 740 can interact with audio subsystem 720 and/or display subsystem 730. For example, input through a microphone or other audio device can provide input or commands for one or more applications or functions of device 700. Additionally, audio output can be provided instead of or in addition to display output. In another example, if display subsystem includes a touchscreen, the display device also acts as an input device, which can be at least partially managed by I/O controller 740. There can also be additional buttons or switches on device 700 to provide I/O functions managed by I/O controller 740.

In one embodiment, I/O controller 740 manages devices such as accelerometers, cameras, light sensors or other environmental sensors, gyroscopes, global positioning system (GPS), or other hardware that can be included in device 700. The input can be part of direct user interaction, as well as providing environmental input to the system to influence its operations (such as filtering for noise, adjusting displays for brightness detection, applying a flash for a camera, or other features). In one embodiment, device 700 includes power management 750 that manages battery power usage, charging of the battery, and features related to power saving operation.

Memory subsystem 760 includes memory device(s) 762 for storing information in device 700. Memory subsystem 760 can include two or more levels of main memory, wherein a first level of main memory (near memory) stores indirection information of a second level of main memory (far memory). The second level of main memory may include wear leveled memory devices, such as nonvolatile (state does not change if power to the memory device is interrupted) memory, for example. The first level of main memory may include volatile (state is indeterminate if power to the memory device is interrupted) memory devices, such as DRAM memory, for example. Memory 760 can store application data, user data, music, photos, documents, or other data, as well as system data (whether long-term or temporary) related to the execution of the applications and functions of system 700. In one embodiment, memory subsystem 760 includes memory controller 764 (which could also be considered part of the control of system 700, and could potentially be considered part of processor 710). Memory controller 764 may include a scheduler to generate and issue commands to memory device 762. Memory controller 764 may include near memory controller functionalities as well as far memory controller functionalities. Alternatively, memory controller 764 may be included in processor 710 rather than in memory subsystem 760.

Connectivity 770 includes hardware devices (e.g., wireless and/or wired connectors and communication hardware) and software components (e.g., drivers, protocol stacks) to enable device 700 to communicate with external devices. The external device could be separate devices, such as other computing devices, wireless access points or base stations, as well as peripherals such as headsets, printers, or other devices.

Connectivity 770 may include multiple different types of connectivity. To generalize, device 700 is illustrated with cellular connectivity 772 and wireless connectivity 774, etc. Connectivity 770 may also include wired connectivity. Cellular connectivity 772 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, LTE (long term evolution—also referred to as “4G”), or other cellular service standards. Wireless connectivity 774 refers to wireless connectivity that is not cellular, and can include personal area networks (such as Bluetooth), local area networks (such as WiFi), and/or wide area networks (such as WiMax), or other wireless communication. Wireless communication refers to transfer of data through the use of modulated electromagnetic radiation through a non-solid medium. Wired communication occurs through a solid communication medium.

Peripheral connections 780 include hardware interfaces and connectors, as well as software components (e.g., drivers, protocol stacks) to make peripheral connections. It will be understood that device 700 could both be a peripheral device (“to” 782) to other computing devices, as well as have peripheral devices (“from” 784) connected to it. Device 700 commonly has a “docking” connector to connect to other computing devices for purposes such as managing (e.g., downloading and/or uploading, changing, synchronizing) content on device 700. Additionally, a docking connector can allow device 700 to connect to certain peripherals that allow device 700 to control content output, for example, to audiovisual or other systems.

In addition to a proprietary docking connector or other proprietary connection hardware, device 700 can make peripheral connections 780 via common or standards-based connectors. Common types can include a Universal Serial Bus (USB) connector (which can include any of a number of different hardware interfaces), DisplayPort including MiniDisplayPort (MDP), High Definition Multimedia Interface (HDMI), Firewire, or other type.

The examples as described herein may be summarized as follows:

Example 1 is a memory module having a capability of read-only operation. The memory module comprises a non-volatile memory, and a controller configured to, in response to a first command from a host, set a memory range of the memory module as a read-only state by storing an address of the memory range with a secret associated with the memory range in an internal database of the memory module, and reject a write command to the memory range in the read-only state.

Example 2 is the memory module of example 1, wherein the controller is further configured to, in response to a second command from the host, set the memory range to a read/write state on a condition that a secret provided with the second command matches the secret stored in the internal database.

Example 3 is the memory module as in any one of examples 1-2, wherein the memory module is an NVDIMM.

Example 4 is the memory module as in any one of examples 1-3, wherein the internal database is stored in the non-volatile memory.

Example 5 is the memory module as in any one of examples 1-4, wherein the internal database is stored in an EEPROM in the memory module.

Example 6 is the memory module as in any one of examples 1-5, wherein the internal database is stored as a part of metadata stored together with NVDIMM pool configuration.

Example 7 is the memory module as in any one of examples 1-6, wherein the controller is further configured to indicate, in response to a third command from the host, whether a secret provided with the third command matches the secret stored in the internal database.

Example 8 is the memory module as in any one of examples 1-7, further comprising a volatile memory on the memory module, and a second controller configured to copy data from the volatile memory to the non-volatile memory using a back-up power source on a condition that a power supply is interrupted and copy the data back to the volatile memory after the power supply is recovered.

Example 9 is the memory module as in any one of examples 1-8, wherein the non-volatile memory is a memory using a PCM technology.

Example 10 is a method for read-only operation of a memory module including a non-volatile memory. The method comprises receiving by the memory module a first command from a host to set a memory range of the memory module to a read-only state, and setting, by the memory module, the memory range to a read-only state by storing an address of the memory range with a secret associated with the memory range in an internal database of the memory module, wherein a write command to the memory range in the read-only state is rejected by the memory module.

Example 11 is the method of example 10, further comprising receiving a second command for setting the memory range to a read/write state, and setting the memory range to the read/write state in response to the second command on a condition that a secret included in the second command matches the secret stored in the internal database.

Example 12 is the method as in any one of examples 10-11, wherein the memory module is an NVDIMM.

Example 13 is the method as in any one of examples 10-12, wherein the internal database is stored in the non-volatile memory.

Example 14 is the method as in any one of examples 10-13, wherein the internal database is stored in an EEPROM in the memory module.

Example 15 is the method as in any one of examples 10-14, wherein the internal database is stored as a part of metadata stored together with NVDIMM pool configuration.

Example 16 is the method as in any one of examples 10-15, further comprising indicating, in response to a third command from the host, whether a secret provided with the third command matches the secret stored in the internal database.

Example 17 is the method as in any one of examples 10-16, wherein the memory module includes a volatile memory module, and the method further comprising copying data from the volatile memory to the non-volatile memory using a back-up power source on a condition that a power supply is interrupted, and copying the data back to the volatile memory after the power supply is recovered.

Example 18 is the method as in any one of examples 10-17, wherein the non-volatile memory is a memory using a PCM technology.

Example 19 is a system having a capability of read-only operation of a memory module. The system comprises a processor, and a memory module. The memory module includes a non-volatile memory, and a controller configured to, in response to a first command from a host, set a memory range of the memory module as a read-only state by storing an address of the memory range with a secret associated with the memory range in an internal database of the memory module, and reject a write command to the memory range in the read-only state.

Example 20 is the system of example 19, wherein the controller is further configured to, in response to a second command from the host, set the memory range to a read/write state on a condition that a secret provided with the second command matches the secret stored in the internal database.

Example 21 is the system as in any one of examples 19-20, wherein the memory module is an NVDIMM.

Example 22 is the system as in any one of examples 19-21, wherein the internal database is stored in the non-volatile memory.

Example 23 is the system as in any one of examples 19-22, wherein the internal database is stored in an EEPROM in the memory module.

Example 24 is the system as in any one of examples 19-23, wherein the internal database is stored as a part of metadata stored together with NVDIMM pool configuration.

Example 25 is the system as in any one of examples 19-24, wherein the controller is further configured to indicate, in response to a third command from the host, whether a secret provided with the third command matches the secret stored in the internal database.

Example 26 is the system as in any one of examples 19-25, wherein the memory module further comprises a volatile memory, and a second controller configured to copy data from the volatile memory to the non-volatile memory using a back-up power source on a condition that a power supply is interrupted and copy the data back to the volatile memory after the power supply is recovered.

Example 27 is the system as in any one of examples 19-26, wherein the non-volatile memory is a memory using a PCM technology.

Example 28 is the system as in any one of examples 19-27, wherein the processor is configured to remove the secret from the system.

Example 29 is the system as in any one of examples 19-28, wherein the processor is configured to authenticate contents on the memory range by verifying the secret stored in the internal database.

Example 30 is a machine-readable storage medium comprising code, when executed, to cause a machine to perform a method for read-only operation of a memory module, wherein the memory module includes a non-volatile memory. The method comprises receiving by the memory module a first command from a host to set a memory range of the memory module to a read-only state, and setting, by the memory module, the memory range to a read-only state by storing an address of the memory range with a secret associated with the memory range in an internal database of the memory module, wherein a write command to the memory range in the read-only state is rejected by the memory module.

Example 31 is the machine-readable storage medium of example 30, wherein the method further comprises receiving a second command to set the memory range to a read/write state, and setting the memory range to the read/write state in response to the second command on a condition that a secret included in the second command matches the secret stored in the internal database.

Example 32 is the machine-readable storage medium as in any one of examples 30-31, wherein the memory module is an NVDIMM.

Example 33 is a memory module having a capability of read-only operation. The memory module comprises means for storage in a non-volatile manner, means for receiving a first command from a host to set a memory range of the means for storage to a read-only state, means for setting the memory range to a read-only state by storing an address of the memory range with a secret associated with the memory range in an internal database of the memory module, and means for rejecting a write command to the memory range in the read-only state.

Example 34 is the memory module of example 33, further comprising means for receiving a second command to set the memory range to a read/write state, and means for setting the memory range to the read/write state in response to the second command on a condition that a secret included in the second command matches the secret stored in the internal database.

Example 35 is the memory module as in any one of examples 33-34, wherein the memory module is an NVDIMM.

Example 36 is the memory module as in any one of examples 33-35, wherein the internal database is stored in the means for storage.

Example 37 is the memory module as in any one of example 33-36, wherein the internal database is stored in an EEPROM in the memory module.

Example 38 is the memory module as in any one of examples 33-37, wherein the internal database is stored as a part of metadata stored together with NVDIMM pool configuration.

Example 39 is the memory module as in any one of examples 33-38, further comprising means for indicating, in response to a third command from the host, whether a secret provided with the third command matches the secret stored in the internal database.

Example 40 is the memory module as in any one of examples 33-39, further comprising means for storage in a volatile manner, and means for copying data from the means for storage in a volatile manner to the means for storage in a non-volatile manner using a back-up power source on a condition that a power supply is interrupted and copying the data back to the means for storage in a volatile manner after the power supply is recovered.

Example 41 is the memory module as in any one of examples 33-40, wherein the means for storage is a memory using a PCM technology.

The aspects and features mentioned and described together with one or more of the previously detailed examples and figures, may as well be combined with one or more of the other examples in order to replace a like feature of the other example or in order to additionally introduce the feature to the other example.

Examples may further be or relate to a computer program having a program code for performing one or more of the above methods, when the computer program is executed on a computer or processor. Steps, operations or processes of various above-described methods may be performed by programmed computers or processors. Examples may also cover program storage devices such as digital data storage media, which are machine, processor or computer readable and encode machine-executable, processor-executable or computer-executable programs of instructions. The instructions perform or cause performing some or all of the acts of the above-described methods. The program storage devices may comprise or be, for instance, digital memories, magnetic storage media such as magnetic disks and magnetic tapes, hard drives, or optically readable digital data storage media. Further examples may also cover computers, processors or control units programmed to perform the acts of the above-described methods or (field) programmable logic arrays ((F)PLAs) or (field) programmable gate arrays ((F)PGAs), programmed to perform the acts of the above-described methods.

The description and drawings merely illustrate the principles of the disclosure. Furthermore, all examples recited herein are principally intended expressly to be only for pedagogical purposes to aid the reader in understanding the principles of the disclosure and the concepts contributed by the inventor(s) to furthering the art. All statements herein reciting principles, aspects, and examples of the disclosure, as well as specific examples thereof, are intended to encompass equivalents thereof.

A functional block denoted as “means for . . . ” performing a certain function may refer to a circuit that is configured to perform a certain function. Hence, a “means for s.th.” may be implemented as a “means configured to or suited for s.th.”, such as a device or a circuit configured to or suited for the respective task.

Functions of various elements shown in the figures, including any functional blocks labeled as “means”, “means for providing a signal”, “means for generating a signal.”, etc., may be implemented in the form of dedicated hardware, such as “a signal provider”, “a signal processing unit”, “a processor”, “a controller”, etc. as well as hardware capable of executing software in association with appropriate software. When provided by a processor, the functions may be provided by a single dedicated processor, by a single shared processor, or by a plurality of individual processors, some of which or all of which may be shared. However, the term “processor” or “controller” is by far not limited to hardware exclusively capable of executing software, but may include digital signal processor (DSP) hardware, network processor, application specific integrated circuit (ASIC), field programmable gate array (FPGA), read only memory (ROM) for storing software, random access memory (RAM), and non-volatile storage. Other hardware, conventional and/or custom, may also be included.

A block diagram may, for instance, illustrate a high-level circuit diagram implementing the principles of the disclosure. Similarly, a flow chart, a flow diagram, a state transition diagram, a pseudo code, and the like may represent various processes, operations or steps, which may, for instance, be substantially represented in computer readable medium and so executed by a computer or processor, whether or not such computer or processor is explicitly shown. Methods disclosed in the specification or in the claims may be implemented by a device having means for performing each of the respective acts of these methods.

It is to be understood that the disclosure of multiple acts, processes, operations, steps or functions disclosed in the specification or claims may not be construed as to be within the specific order, unless explicitly or implicitly stated otherwise, for instance for technical reasons. Therefore, the disclosure of multiple acts or functions will not limit these to a particular order unless such acts or functions are not interchangeable for technical reasons. Furthermore, in some examples a single act, function, process, operation or step may include or may be broken into multiple sub-acts, -functions, -processes, -operations or -steps, respectively. Such sub acts may be included and part of the disclosure of this single act unless explicitly excluded.

Furthermore, the following claims are hereby incorporated into the detailed description, where each claim may stand on its own as a separate example. While each claim may stand on its own as a separate example, it is to be noted that—although a dependent claim may refer in the claims to a specific combination with one or more other claims—other examples may also include a combination of the dependent claim with the subject matter of each other dependent or independent claim. Such combinations are explicitly proposed herein unless it is stated that a specific combination is not intended. Furthermore, it is intended to include also features of a claim to any other independent claim even if this claim is not directly made dependent to the independent claim.

1. A memory module having a capability of read-only operation, comprising:
a non-volatile memory; and
a controller configured to, in response to a first command from a host, set a memory range of the memory module as a read-only state by storing an address of the memory range with a secret associated with the memory range in an internal database of the memory module, and reject a write command to the memory range in the read-only state,
wherein the controller is further configured to indicate to the host, in response to a second command from the host, whether a secret provided with the second command matches the secret stored in the internal database.

2. The memory module of claim 1, wherein the controller is further configured to, in response to a third command from the host, set the memory range to a read/write state on a condition that a secret provided with the third command matches the secret stored in the internal database.

3. The memory module of claim 2, wherein the memory module is a non-volatile dual in-line memory module (NVDIMM).

4. The memory module of claim 1, wherein the internal database is stored either in the non-volatile memory, in an electrically erasable programmable read only memory (EEPROM) in the memory module, or as a part of metadata stored together with non-volatile dual in-line memory module (NVDIMM) pool configuration.

5. (canceled)

6. The memory module of claim 1, further comprising
a volatile memory on the memory module; and
a second controller configured to copy data from the volatile memory to the non-volatile memory using a back-up power source on a condition that a power supply is interrupted and copy the data back to the volatile memory after the power supply is recovered.

7. The memory module of claim 1, wherein the non-volatile memory is a memory using a phase change memory (PCM) technology.

8. A method for read-only operation of a memory module including a non-volatile memory, the method comprising:
receiving by the memory module a first command from a host to set a memory range of the memory module to a read-only state;
setting, by the memory module, the memory range to a read-only state by storing an address of the memory range with a secret associated with the memory range in an internal database of the memory module, wherein a write command to the memory range in the read-only state is rejected by the memory module; and
indicating to the host, in response to a second command from the host, whether a secret provided with the second command matches the secret stored in the internal database.

9. The method of claim 8, further comprising:
receiving a third command for setting the memory range to a read/write state; and
setting the memory range to the read/write state in response to the third command on a condition that a secret included in the third command matches the secret stored in the internal database.

10. The method of claim 9, wherein the memory module is a non-volatile dual in-line memory module (NVDIMM).

11. The method of claim 8, wherein the internal database is stored either in the non-volatile memory, in an electrically erasable programmable read only memory (EEPROM) in the memory module, or as a part of metadata stored together with non-volatile dual in-line memory module (NVDIMM) pool configuration.

12. (canceled)

13. The method of claim 8, wherein the memory module includes a volatile memory module, and the method further comprising:
copying data from the volatile memory to the non-volatile memory using a back-up power source on a condition that a power supply is interrupted; and
copying the data back to the volatile memory after the power supply is recovered.

14. The method of claim 8, wherein the non-volatile memory is a memory using a phase change memory (PCM) technology.

15. A system having a capability of read-only operation of a memory module, comprising:
a processor; and
a memory module including:
a non-volatile memory; and
a controller configured to, in response to a first command from a host, set a memory range of the memory module as a read-only state by storing an address of the memory range with a secret associated with the memory range in an internal database of the memory module, and reject a write command to the memory range in the read-only state,
wherein the controller is further configured to indicate to the host, in response to a second command from the host, whether a secret provided with the second command matches the secret stored in the internal database.

16. The system of claim 15, wherein the controller is further configured to, in response to a third command from the host, set the memory range to a read/write state on a condition that a secret provided with the third command matches the secret stored in the internal database.

17. The system of claim 16, wherein the memory module is a non-volatile dual in-line memory module (NVDIMM).

18. The system of claim 15, wherein the internal database is stored either in the non-volatile memory, in an electrically erasable programmable read only memory (EEPROM) in the memory module, or as a part of metadata stored together with non-volatile dual in-line memory module (NVDIMM) pool configuration.

19. (canceled)

20. The system of claim 15, wherein the memory module further comprises:
a volatile memory; and
a second controller configured to copy data from the volatile memory to the non-volatile memory using a back-up power source on a condition that a power supply is interrupted and copy the data back to the volatile memory after the power supply is recovered.

21. The system of claim 15, wherein the non-volatile memory is a memory using a phase change memory (PCM) technology.

22. The system of claim 15, wherein the processor is configured to remove the secret from the system.

23. The system of claim 15, wherein the processor is configured to authenticate contents on the memory range by verifying the secret stored in the internal database.

24. A non-transient machine-readable storage medium comprising code, when executed, to cause a machine to perform a method for read-only operation of a memory module, wherein the memory module includes a non-volatile memory, the method comprising:
receiving by the memory module a first command from a host to set a memory range of the memory module to a read-only state;
setting, by the memory module, the memory range to a read-only state by storing an address of the memory range with a secret associated with the memory range in an internal database of the memory module, wherein a write command to the memory range in the read-only state is rejected by the memory module; and
indicating to the host, in response to a second command from the host, whether a secret provided with the second command matches the secret stored in the internal database.

25. The non-transient machine-readable storage medium of claim 24, wherein the method further comprises:
receiving a third command to set the memory range to a read/write state; and
setting the memory range to the read/write state in response to the third command on a condition that a secret included in the third command matches the secret stored in the internal database.
